(19) United States
(12) Patent Application Publication
(10) Pub. No.: US 2021/0082811 A1
(43) Pub. Date: Mar. 18, 2021

(54) FABRICATION OF INTEGRATED CIRCUIT INCLUDING PASSIVE ELECTRICAL COMPONENT

(71) Applicants: Scott WARRICK, Austin, TX (US); Cirrus Logic International Semiconductor Ltd., Edinburgh (GB)

(72) Inventors: Scott WARRICK, Austin, TX (US); cHRISTIAN LARSEN, Austin, TX (US); Eric J. KING, Austin, TX (US); John L. MELANSON, Austin, TX (US); Anthony S. DOY, Boulder, CO (US); David M. BIVEN, Austin, TX (US)

(73) Assignee: Cirrus Logic International Semiconductor Ltd., Edinburgh (GB)

(21) Appl. No.: 16/954,430

(22) PCT Filed: Feb. 12, 2019
(86) PCT No.: PCT/US2019/017711

§ 371 Date: Jun. 16, 2020

Related U.S. Application Data
(60) Provisional application No. 62/629,996, filed on Feb. 13, 2018.

(51) Int. Cl. H01L 23/522; H01L 23/31; H01L 23/00

(52) U.S. Cl. CPC H01L 23/5227; H01L 23/3114; H01L 2224/12105; H01L 24/11; H01L 24/14

(57) ABSTRACT

A method for fabricating an integrated circuit upon a substrate may include forming a passive electrical component in a non-final layer of the integrated circuit and forming one or more electrical contacts in a final layer of the integrated circuit such that the one or more electrical contacts and the passive electrical component are positioned in a manner such that an imaginary line perpendicular to and from a surface of the substrate intersects the passive electrical component and the one or more electrical contacts.

### RELATED APPLICATION

The present disclosure claims priority to U.S. Provisional Patent Application Ser. No. 62/629,996, filed Feb. 13, 2018, which is incorporated by reference herein in its entirety.

### FIELD OF DISCLOSURE

The present disclosure relates in general to semiconductor fabrication, and more particularly, to fabrication of and use of a dual-gate metal-oxide-semiconductor field-effect transistor.

### BACKGROUND

Semiconductor device fabrication is a process used to create integrated circuits that are present in many electrical and electronic devices. It is a multiple-step sequence of photolithographic, mechanical, and chemical processing steps during which electronic circuits are gradually created on a wafer made of semiconducting material. For example, during semiconductor device fabrication, numerous discrete circuit components, including transistors, resistors, capacitors, inductors, and diodes may be formed on a single semiconductor die.

An inductor is a passive circuit component with many uses. Generally speaking, an inductor is a passive two-terminal electrical component that stores energy in a magnetic field when electric current flows through it. Inductors formed within integrated circuits may be used in tuning circuits, inductive-based sensors, transformers, and/or other uses.

Using existing fabrication techniques, formation of an inductor on a semiconductor surface has the disadvantage of using surface area of an integrated circuit that could otherwise be used for placement of conductive material, such as bumps, for electrically coupling the integrated circuit to other components external to the integrated circuit. For example, FIG. 4 illustrates a top plan view of a portion of a semiconductor substrate 1 with an inductor 4 fabricated on a surface 2 of semiconductor substrate 1, wherein inductor 4 comprises magnetic material 14 surrounded by a coil 10 of electrically conductive material 8, as is known in the art. As seen in FIG. 4, formation of inductor 4 on surface 2 uses area of surface 2 that could otherwise be used for bumps 28 in the absence of inductor 4.

Accordingly, techniques are desired for forming an inductor or other passive electrical component in an integrated circuit while still maximizing available surface area of the integrated circuit for placement of conductive material.

### SUMMARY

In accordance with the teachings of the present disclosure, certain disadvantages and problems associated with fabrication of passive electrical components in an integrated circuit may be reduced or eliminated.

In accordance with embodiments of the present disclosure, a method for fabricating an integrated circuit upon a substrate may include forming a passive electrical component in a non-final layer of the integrated circuit and forming one or more electrical contacts in a final layer of the integrated circuit such that the one or more electrical contacts and the passive electrical component are positioned in a manner such that an imaginary line perpendicular to and from a surface of the substrate intersects the passive electrical component and the one or more electrical contacts.

In accordance with these and other embodiments of the present disclosure, an integrated circuit fabricated upon a substrate may include a passive electrical component formed in a non-final layer of the integrated circuit and one or more electrical contacts formed in a final layer of the integrated circuit such that the one or more electrical contacts and the passive electrical component are positioned in a manner such that an imaginary line perpendicular to and from a surface of the substrate intersects the passive electrical component and the one or more electrical contacts.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a side cross-sectional elevation view of a portion of a semiconductor substrate with a passive electrical component fabricated thereon, in accordance with embodiments of the present disclosure;

FIG. 2 illustrates a top plan view of a portion of a semiconductor substrate with a passive electrical component fabricated thereon, in accordance with embodiments of the present disclosure;

FIG. 3 illustrates an isometric perspective view of a portion of a semiconductor substrate with a passive electrical component fabricated thereon, in accordance with embodiments of the present disclosure; and

FIG. 4 illustrates a top plan view of a portion of a semiconductor substrate with a passive electrical component upon a surface of the semiconductor substrate, as is known in the art.

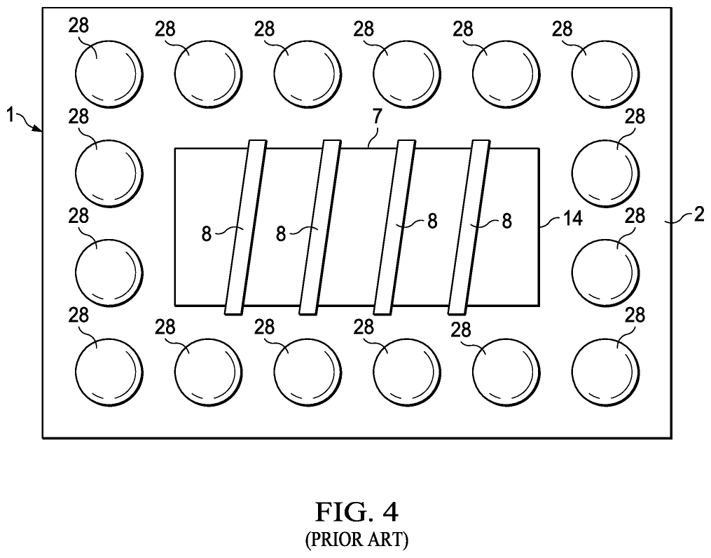

### DETAILED DESCRIPTION

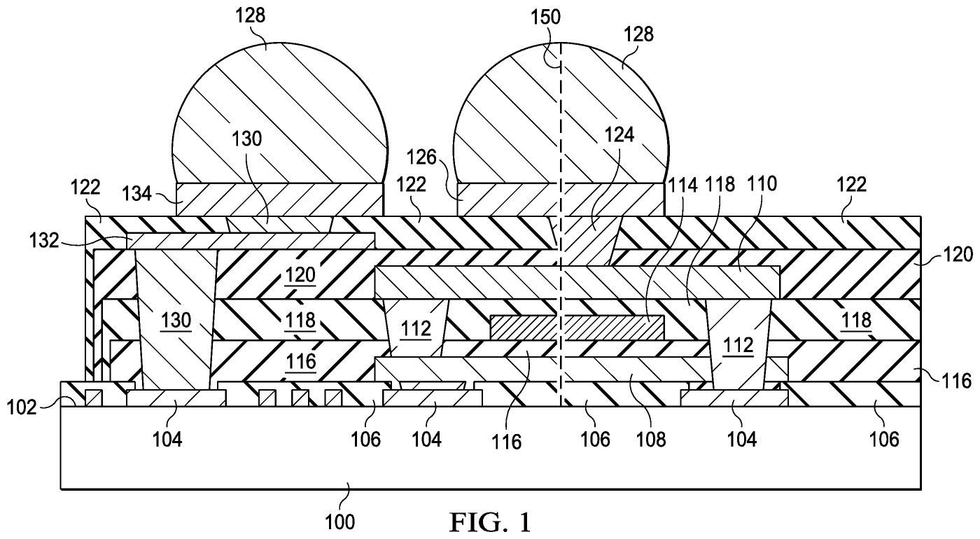

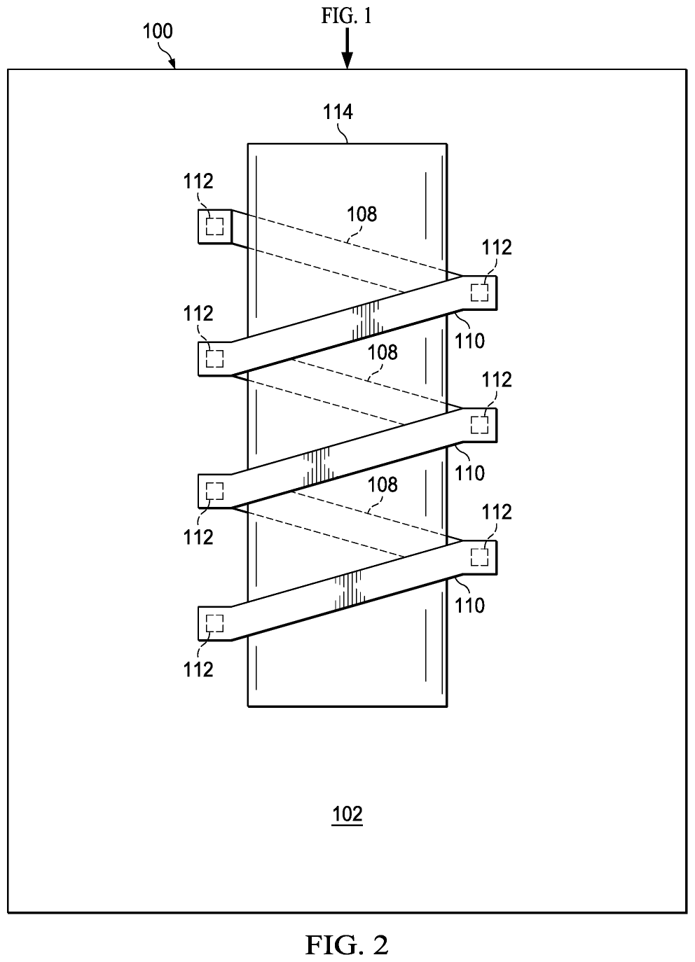

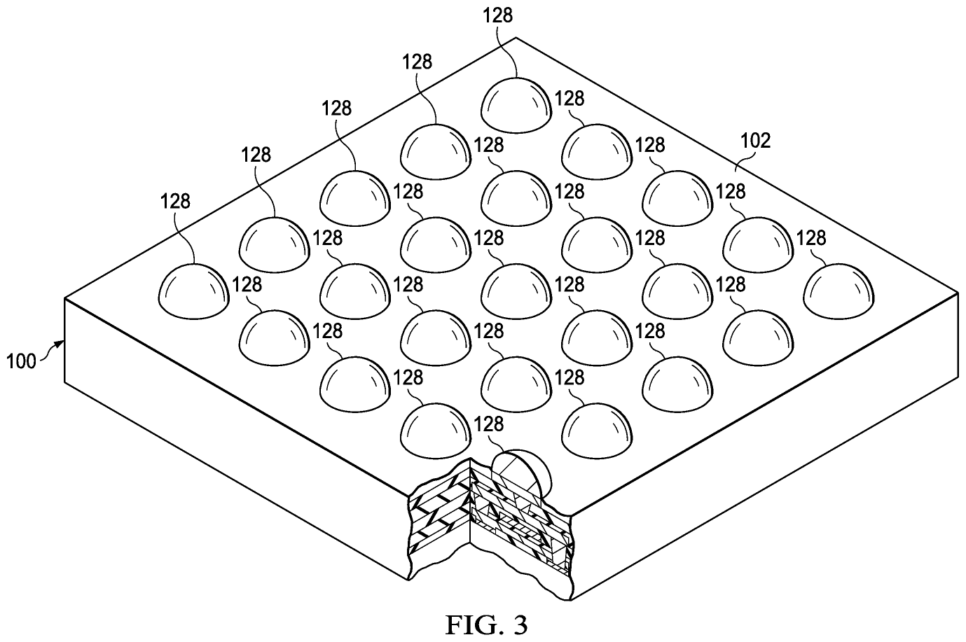

FIG. 1 illustrates a side cross-sectional elevation view of a portion of a semiconductor substrate 100 with a passive electrical component fabricated thereon, in accordance with embodiments of the present disclosure. FIG. 2 illustrates a top plan view of a portion of semiconductor substrate 100 with a passive electrical component fabricated thereon, in accordance with embodiments of the present disclosure. FIG. 3 illustrates an isometric perspective view of a portion of semiconductor substrate 100 with a passive electrical component fabricated thereon, in accordance with embodiments of the present disclosure. FIGS. 1-3 may be generally referred to herein as “the FIGURES.”

Semiconductor substrate 100 may be formed of any suitable material including without limitation silicon, silicon carbide, germanium, gallium phosphide, gallium nitride, gallium arsenide, indium phosphide, indium nitride, indium arsenide, etc. Although not explicitly shown in the FIGURES, numerous devices (e.g., transistors, resistors, etc.) may be formed within semiconductor substrate 100 to create an integrated circuit. To provide appropriate electrical connectivity, metallization 104 may be formed at appropriate locations on a surface 102 of semiconductor substrate 100 using known techniques. In addition, to provide appropriate electrical insulation, electrically-insulative material 106 (e.g., a semiconductor oxide) may also be formed at appropriate locations on surface 102 of semiconductor substrate 100 using known techniques.

In some instances, it may be desirable or necessary to form some electrical components of an integrated circuit on top of surface 102 of semiconductor substrate 100. For example, fabrication of certain devices within semiconductor material, such as inductors or electrical transformers, may not be feasible or even possible. The FIGURES depict formation of a passive electrical component, in particular an inductor, above surface 102 of semiconductor substrate 100, as described in greater detail below.

As is known in the art, an inductor is often formed by wrapping a coil of electrically-conductive wire around a ferromagnetic core of magnetic material. To achieve the same effect on semiconductor substrate 100, a first metallization layer 108, a second metallization layer 110, component vias 112, and magnetic material 114 may be formed above surface 102 (e.g., upon electrically-insulative material 106) and arranged to mimic a coil (with first metallization layer 108, second metallization layer 110, and component vias 112 forming the coil) wrapped around a ferromagnetic core (with magnetic material 114 serving as the ferromagnetic core). For example, after metallization 104 and electrically-insulative material 106 are formed on surface 102 and polished/machined to planarize metallization 104 and electrically-insulative material 106, first metallization layer 108 may be formed upon metallization 104 and electrically-insulative material 106 at desired locations (e.g., as shown in FIG. 1, first metallization layer 108 may be coupled to metallization 104 in order to electrically couple the passive electrical component being formed on surface 102 to a device formed below surface 102). Subsequently, a first insulative layer 116 (e.g., a polymer material) may be formed over first metallization layer 108, metallization 104, and electrically-insulative material 106 in order to electrically insulate first metallization layer 108 from other integrated circuit components. Then, first insulative layer 116 may be polished/machined to planarize first insulative layer 116. After such polishing/machining, magnetic material 114 may be formed on first insulative layer 116 in a desired location proximate (e.g., above first metallization layer 108 taken in a direction perpendicular to a plane defined by surface 102) to first metallization layer 108, as shown by vertical dashed line 150 in FIG. 1.

Next, a second insulative layer 118 (e.g., a polymer material) may be formed over magnetic material 114 and first insulative layer 116 in order to electrically insulate magnetic material 114 from other integrated circuit components. Second insulative layer 118 may then be polished/machined to planarize second insulative layer 118. After such polishing/machining, component vias 112 may be formed through first insulative layer 116 and second insulative layer 118 to electrically couple second metallization layer 110 to first metallization layer 108 and/or metallization 104, as desired. Then, second metallization layer 110 may be formed upon second insulative layer 118 and component vias 112 at desired locations (e.g., as shown in FIG. 1, second metallization layer 110 be formed proximate to magnetic material 114 and may be coupled to electrically-conductive material, such as via 124, bump pad 126, and bump 128) in order to electrically couple the passive electrical component being formed on surface 102 to a device or other circuitry external to the integrated circuit formed within and upon semiconductor substrate 100.

Then, a third insulative layer 120 (e.g., a polymer material) may be formed over second metallization layer 110 and second insulative layer 118 in order to electrically insulate second metallization layer 110 from other integrated circuit components. Third insulative layer 120 may then be polished/machined to planarize second insulative layer 120. One or more additional insulative layers (e.g., a fourth insulative layer 122) may be formed over a third insulative layer 120.

To provide electrical coupling of second metallization layer 110 to devices external to the integrated circuit formed within and upon semiconductor substrate 100, an electrically-conductive via 124 may be formed within third insulative layer 120 and fourth insulative layer 122, with an electrically-conductive bump pad 126. A bump 128 (e.g., a solder bump) may be formed upon bump pad 126, wherein such bump 128 may be one of an array of bumps 128 (e.g., as in a “flip-chip” architecture) which provide an interface for electrical conductivity to the integrated circuit formed within and upon semiconductor substrate 100.

As also shown in the FIGURES, other vias 130, metallization layers 132, and bump pads 134 may be formed within and/or upon the various insulative layers 116, 118, 120, and 122 in order to provide electrical coupling to electrical components formed within semiconductor substrate 100 to components external to the integrated circuit formed within and upon semiconductor substrate 100.

In accordance with the discussion above, methods and systems for fabricating an integrated circuit upon a semiconductor substrate, and an integrated circuit formed from such methods and systems, may be provided. For example, a method for fabricating an integrated circuit upon a substrate (e.g., semiconductor substrate 100) may include forming a passive electrical component (e.g., an inductor formed by a first metallization layer 108, second metallization layer 110, components vias 112, and magnetic material 114) in a non-final layer (e.g., layers other than fourth insulative layer 122) of the integrated circuit. The method may also include forming one or more electrical contacts (e.g., via 124, bump pad 126, bump 128) in a final layer (e.g., fourth insulative layer 122) of the integrated circuit such that the one or more electrical contacts and the passive electrical component are positioned in a manner such that an imaginary line perpendicular to and from a surface (e.g., surface 102) of the substrate intersects the passive electrical component and the one or more electrical contacts. In addition, the passive electrical component comprises a magnetic-based component (e.g., includes magnetic material 114). As discussed above, such magnetic-based component may include an inductor or a transformer. Also as discussed above, the one or more electrical contacts comprise at least one of an electrical bump (e.g., bump 128). In these and other embodiments, semiconductor substrate 100 may be part of a wafer-level chip scale package (WLCSP).

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method for fabricating an integrated circuit upon a substrate, comprising:
forming a passive electrical component in a non-final layer of the integrated circuit; and
forming one or more electrical contacts in a final layer of the integrated circuit such that the one or more electrical contacts and the passive electrical component are positioned in a manner such that an imaginary line perpendicular to and from a surface of the substrate intersects the passive electrical component and the one or more electrical contacts.

2. The method of claim 1, wherein the passive electrical component comprises a magnetic-based component.

3. The method of claim 2, wherein the magnetic-based component comprises an inductor.

4. The method of claim 2, wherein the magnetic-based component comprises a transformer.

5. The method of claim 1, wherein the one or more electrical contacts comprises an electrical bump.

6. The method of claim 1, wherein the substrate is part of a wafer-level chip scale package (WLCSP).

7. An integrated circuit fabricated upon a substrate, comprising:
a passive electrical component formed in a non-final layer of the integrated circuit; and
one or more electrical contacts formed in a final layer of the integrated circuit such that the one or more electrical contacts and the passive electrical component are positioned in a manner such that an imaginary line perpendicular to and from a surface of the substrate intersects the passive electrical component and the one or more electrical contacts.

8. The integrated circuit of claim 7, wherein the passive electrical component comprises a magnetic-based component.

9. The integrated circuit of claim 8, wherein the magnetic-based component comprises an inductor.

10. The integrated circuit of claim 8, wherein the magnetic-based component comprises a transformer.

7. The integrated circuit of claim 7, wherein the one or more electrical contacts comprises an electrical bump.

12. The integrated circuit of claim 7, wherein the substrate is part of a wafer-level chip scale package (WLCSP).
